(19) United States
(12) Patent Application Publication
(10) Pub. No.: US 2007/0077735 A1
(43) Pub. Date: Apr. 5, 2007

(54) Element of low temperature poly-silicon thin film and method of making poly-silicon thin film by direct deposition at low temperature and inductively-coupled plasma chemical vapor deposition equipment therefor

(75) Inventors: I-Hsuan Peng, Hsinchu (TW); Chin-Jen Huang, Hsinchu (TW); Liang-Tang Wang, Hsinchu (TW); Jung-Fang Chang, Hsinchu (TW); Te-Chi Wong, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/395,215

(22) Filed: Apr. 3, 2006

(30) Foreign Application Priority Data
Oct. 4, 2005 (TW) 094135976

(51) Int. Cl. H01L 21/20

(52) U.S. Cl. 438/486; 438/488

(57) ABSTRACT

A low temperature poly-silicon thin film element, method of making poly-silicon thin film by direct deposition at low temperature, and the inductively-coupled plasma chemical vapor deposition equipment utilized, wherein the poly-silicon material is induced to crystallize into a poly-silicon thin film at low temperature by means of high density plasma and substrate bias voltage. Furthermore, the atom structure of the poly-silicon thin film is aligned in regular arrangement by making use of the induction layer having optimal orientation and lattice constant close to that of the silicon, thus raising the crystallization quality of the poly-silicon thin film and reducing the thickness of the incubation layer.

### BACKGROUND OF THE INVENTION

1. Field of Invention

The invention relates a poly-silicon thin film and method of formation and in particular to a low temperature poly-silicon thin film element, method of making poly-silicon thin film by direct deposition at low temperature and the inductively-coupled plasma chemical vapor deposition equipment utilized.

2. Related Art

Nowadays, in the manufacturing of various devices such as a semiconductor, thin film solar cell and liquid crystal display (LCD), a silicon thin film is required. The silicon thin film has to be deposited at low temperature below 600° C. by means of Physical Vapor Deposition (PVD), Plasma Enhanced Chemical Vapor Deposition (PE-CVD), or Chemical Vapor Deposition (CVP). However, during the deposition process, an amorphous silicon (a-Si) thin film is formed instead of poly-silicon (poly-Si) thin film due to the insufficient energy provided. Since the arrangement of silicon crystallization of poly-silicon is more orderly than that of amorphous silicon, the poly-silicon has high electron mobility and low temperature sensitivity.

Presently, the technology of a Solid Phase Crystallization or Excimer Laser Annealing (ELA) is utilized to form a poly-silicon thin-film, so that the amorphous silicon on a thin film is crystallized into poly-silicon through high temperature annealing, thus realizing a poly-silicon structure.

However, in utilizing the Solid Phase Crystallization, a high crystallization temperature is required, thus a silicon wafer or Quartz (SiO3) must be used as substrate. Since these materials are pretty expensive they are not suitable for mass production.

Moreover, in utilizing the Excimer Laser Annealing, though the crystallization temperature may be reduced, yet the cost of the equipment used is pretty high. Besides, the formation speed of laser scanning is not very satisfactory.

In recent years, the Plasma Enhanced Chemical Vapor Deposition (PE-CVD) and Hot Wire Chemical Vapor Deposition (HW-CVD) are developed to directly deposit the poly-silicon material. However, in the preliminary stage of the deposition of the poly-silicon thin film, the nucleation density is too low, thus it must be deposited to reach several thousands Armstrong (>1000Å) to form the poly-silicon thin film of better crystallization.

In addition to the direct deposition method, the technology of Metal-Induced lateral Crystallization (MILC) is developed to deposit a thinner layer of poly-silicon at slower speed, to be used as a seed layer for the subsequent deposition of amorphous silicon. The speed of the gas flow utilized in depositing the poly-silicon is slower than that normally used in depositing the amorphous silicon by several folds, then an appropriate thickness of amorphous silicon is deposited on the poly-silicon just formed and is annealed in a furnace of 600° C., so that the amorphous silicon is crystallized into poly-silicon. Since the seed layer already exists, the amorphous silicon can be transformed into poly-silicon in a very short period of time. However, since it takes too long to form the seed layer at low speed, there is hardly any saving of time for the entire process from the start of deposition to the completion of anneal. Furthermore, in the application of the technology of Metal-Induced lateral Crystallization (MILC), the overly high co-melting point of metal and silicon must be considered, besides, there are the problems of the contamination of the thin film by metals, thus, this technology is not suitable for mass production. In addition, the application of the seed layer in helping the formation of thin-film thereon has the insurmountable problem of an overly high temperature of the substrate.

### SUMMARY OF THE INVENTION

To overcome and improve the above-mentioned shortcomings and drawbacks of the prior art, the object of the invention is to provide a low temperature poly-silicon thin film element, a method of making a poly-silicon thin film by direct deposition at low temperature and the inductively-coupled plasma chemical vapor deposition equipment utilized, so as to solve the problem of the prior art.

Through the application of the low temperature poly-silicon thin film element, the method of making the poly-silicon thin film by direct deposition at low temperature and the inductively-coupled plasma chemical vapor deposition equipment utilized, the quality of the thin film thus produced can be improved significantly.

Furthermore, through the application of the low temperature poly-silicon thin film element, the method of making the poly-silicon thin film by direct deposition at low temperature and the inductively-coupled plasma chemical vapor deposition equipment utilized, the thickness of the incubation layer can be reduced.

Therefore, to achieve the above-mentioned object, the invention discloses a method of making a poly-silicon thin film by direct deposition at low temperature, including the following steps: Firstly, provide a substrate, next apply a bias voltage on the substrate and depositing the poly-silicon material on the substrate by means of Plasma Enhanced Chemical Vapor Deposition (PE-CVD). The poly-silicon material is crystallized into poly-silicon thin film through the bias voltage applied, thus the silicon atoms on the surface of the poly-silicon material are enabled to have sufficient diffusion energy through the bias voltage applied, so that the degree of crystallization of poly-silicon material can be raised to form the poly-silicon thin film at low substrate temperature.

In the above process, the plasma enhanced chemical vapor deposition can be the ordinary Plasma Enhanced Chemical Vapor Deposition (PE-CVD) or the Inductively-Coupled Plasma Chemical Vapor Deposition (ICP-CVD).

In general, the Inductively-Coupled Plasma Chemical Vapor Deposition mentioned above includes the following steps: Firstly, place a substrate in a vacuum chamber. Next, inject a gas containing poly-silicon material into the vacuum chamber. Then, an induction coil is utilized to generate an inductively coupled electrical field in the vacuum chamber, so that the injected gas is transformed into high density plasma. And finally, this high density plasma is diffused into the substrate, hereby realizing the deposition of the poly-silicon material on the surface of a substrate.

In addition, the invention discloses another method of making a poly-silicon thin film by direct deposition at low temperature, including the following steps: Firstly, provide a substrate. Next, deposit a material having predetermined lattice constant on the substrate to form an induction layer having optimal orientation. And finally, deposit poly-silicon material on the induction layer by making use of Plasma Enhanced Chemical Vapor Deposition (PE-CVD), so that the poly-silicon material is crystallized into poly-silicon thin film through the induction of the induction layer. As such, the induction layer may serve as an ideal place for the bonding arrangement of silicon atoms of poly-silicon material, so that poly-silicon material may crystallize into a poly-silicon thin film at low temperature.

In the above process, the value of the predetermined lattice constant is close to the lattice constant of silicon, thus the material having the predetermined lattice constant may include the material such as aluminum nitride (AIN). Besides, the induction layer may be formed by means of chemical vapor deposition (CVD), physical vapor deposition (PVD) or atomic layer deposition (ALD), thus the poly-silicon thin film may be formed by directly depositing the poly-silicon material on the induction layer through the ordinary Plasma Enhanced Chemical Vapor Deposition (PE-CVD) or Inductively-Coupled Plasma Chemical Vapor Deposition (ICP-CVD).

Moreover, the method of Inductively-Coupled Plasma Chemical Vapor Deposition includes the following steps: Firstly, place a substrate in a vacuum chamber. Next, inject a gas containing poly-silicon material into the vacuum chamber. Then, an induction coil is utilized to generate inductively coupled electrical field in the vacuum chamber, so that the injected gas is transformed into high density plasma. And finally, this high density plasma is diffused into the substrate, hereby realizing the deposition of the poly-silicon material on the surface of a substrate.

Furthermore, the invention discloses a low temperature poly-silicon thin film element, which includes: a substrate, an induction layer and a poly-silicon thin film. Thus, the induction layer is formed on the substrate; the poly-silicon thin film is formed on the induction layer, wherein, the induction layer is provided with a predetermined lattice constant and optimal orientation.

In the above process, the value of the predetermined lattice constant is close to the lattice constant of silicon, thus the material having the predetermined lattice constant may include a material such as aluminum nitride (AIN). Besides, the induction layer may be formed by means of chemical vapor deposition (CVD), physical vapor deposition (PVD) or atomic layer deposition (ALD), thus the poly-silicon thin film may be formed by directly depositing the poly-silicon material on the induction layer through the ordinary Plasma Enhanced Chemical Vapor Deposition (PE-CVD) or Inductively-Coupled Plasma Chemical Vapor Deposition (ICP-CVD).

Besides, a gate electrode may be disposed between a substrate and an induction layer. As such, in manufacturing semiconductor elements, the induction layer could serve as a gate insulation layer, hereby reducing the production cost and time.

In addition, the invention further discloses an equipment of the inductively-coupled plasma chemical vapor deposition, which is utilized in depositing a low temperature poly-silicon thin film on a substrate. The equipment of the inductively-coupled plasma chemical vapor deposition includes: a vacuum chamber, an induction coil, and a direct current (DC) bias voltage supply. The induction coil and DC bias voltage supply is disposed outside the vacuum chamber, and in the vacuum chamber a support stand is provided to place the substrate. In the application of the equipment, more than one kind of gas containing poly-silicon material is injected into the vacuum chamber, which is transformed into plasma through the inductively-coupled electric field generated by the induction coil, so the plasma thus generated is diffused in the surface of a substrate to create the absorption, reaction, and migration effects, so that the poly-silicon material is deposited on the substrate. Meanwhile, a bias voltage provided by the DC bias voltage supply that is electrically connected to the support stand is applied on the substrate to expedite the poly-silicon material to crystallize into a poly-silicon thin film.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given in the illustration below only, and thus is not limitative of the present invention, wherein:

FIG. 1 is a flowchart of the steps of a method of making a poly-silicon thin film by direct deposition at low temperature according to a first embodiment of the invention;

FIG. 2 is a schematic diagram of a structure of a low temperature poly-silicon thin film element according to the first embodiment of the invention;

FIG. 3 is a schematic diagram of the equipment of Inductively-Coupled Plasma Chemical Vapor Deposition (ICP-CVD) according to the first embodiment of the invention;

FIG. 4 is a flowchart of the steps of a method of making a poly-silicon thin film by direct deposition at low temperature according to a second embodiment of the invention;

FIG. 5 is a schematic diagram of a structure of a low temperature poly-silicon thin film element according to the second embodiment of the invention;

FIG. 6 is a Raman spectrum of a low temperature poly-silicon thin film according to an embodiment of the invention; and

FIG. 7 is a schematic diagram of a structure of a low temperature poly-silicon thin film transistor according to an embodiment of the invention.

### DETAILED DESCRIPTION OF THE INVENTION

The purpose, construction, features, and functions of the invention can be appreciated and understood more thoroughly through the following detailed description with reference to the attached drawings.

First of all, the major essence of the invention lies in the concept of utilizing the high density plasma and induced crystallization to improve the quality of the deposited thin film and reduce the thickness of the incubation layer.

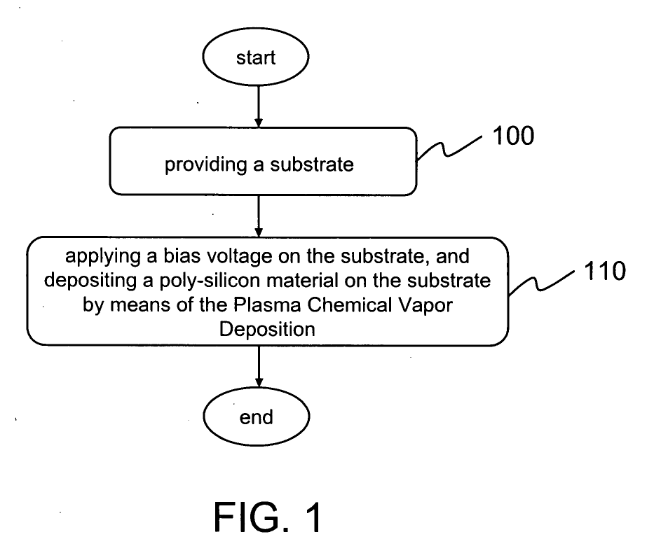

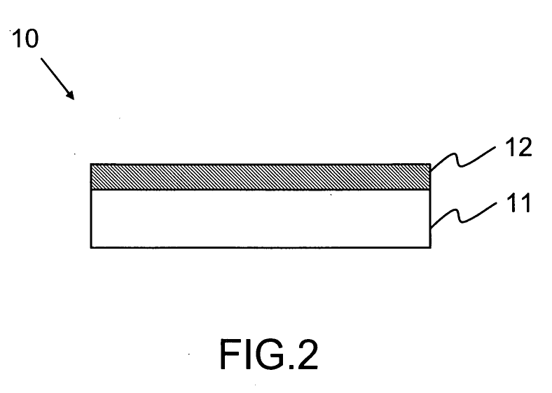

Referring to FIG. 1, a flowchart of the steps of a method of making a poly-silicon thin film by direct deposition at low temperature according to a first embodiment of the invention is shown. The steps include: Firstly, provide a substrate (step 100). Next, apply a bias voltage on the substrate and depositing poly-silicon material on the substrate by means of Plasma Enhanced Chemical Vapor Deposition (step 110). In the above step, the bias voltage may be applied to the substrate immediately before or after the start of deposition of the poly-silicon material on the substrate, or the two actions may be carried on simultaneously. As such, through the supply of high density plasma coupled with the bias voltage applied on the substrate, the silicon atoms on the surface of the poly-silicon material may have sufficient diffusion energy to form a more regular arrangement, hereby enabling the crystallization of the poly-silicon material into the poly-silicon thin film at low temperature. Thus, through the application of the present embodiment, the poly-silicon thin film element 10 consisting of a substrate 11 and a poly-silicon thin film 12 can be realized as shown in FIG. 2.

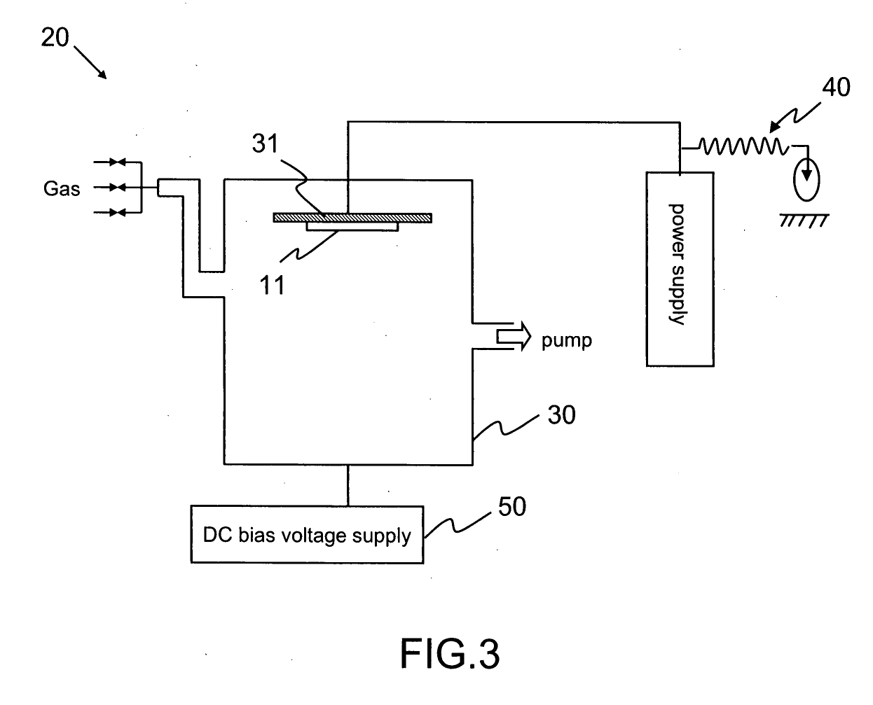

In the present embodiment, in addition to the equipment of the ordinary Plasma Enhanced Chemical Vapor Deposition, the equipment of another Inductively-Coupled Plasma Chemical Vapor Deposition (ICP-CVD) may be used to achieve the deposition of the poly-silicon thin film. As shown in FIG. 3, the equipment 20 of inductively-coupled plasma chemical vapor deposition includes: a vacuum chamber 30, an inductive coil 40, and a DC bias voltage supply 50. The vacuum chamber 30 is capable of accommodating the injection of more than one kind of gas, and is provided with a support stand 31 to place a substrate 11. A DC bias voltage supply 50 is electrically connected to the substrate 11, the induction coil 40 and the DC bias voltage supply 50 are both disposed outside the vacuum chamber 30, and are utilized to generate plasma and provide bias voltage respectively.

When gas is injected into the vacuum chamber 30, it is turned into high density plasma through the action of the electrical field generated by the inductive coupling of the induction coil 40, thus the plasma diffused into the substrate 11 will produce the effects of absorption, reaction, and migration, thus the poly-silicon material is deposited on the substrate 11 .The poly-silicon material deposited on the substrate 11 under influence of the bias voltage applied by the DC bias voltage supply on the substrate 11 will make the heat generated by the bombardment of substrate 11 by the ions transmit smoothly to the silicon atoms on the surface of the poly-silicon material, such that the silicon atoms may have sufficient diffusion energy to raise the degree of crystallization of the poly-silicon material and produce the poly-silicon thin film 12 at low substrate temperature.

In addition, before the implementation of deposition of the poly-silicon material, an induction layer of optimal orientation, having lattice constant close to that of silicon such as AIN, is deposited, then the induction layer is utilized as the ideal place for the bonding arrangement of silicon atoms of poly-silicon nucleation, thus depositing and forming the poly-silicon thin film of superior quality.

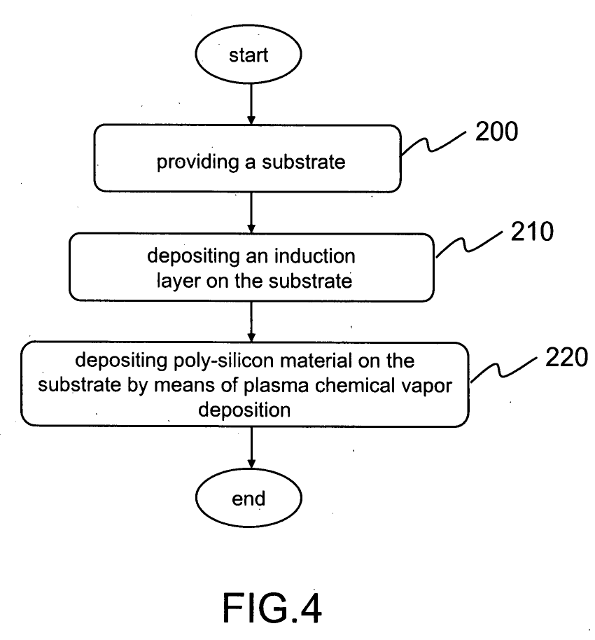

Subsequently, referring to FIG. 4, a flowchart of the steps of the method of making a poly-silicon thin film by direct deposition at low temperature according to a second embodiment of the invention is shown. The steps include: Firstly, provide a substrate (step 200). Next, depositing a material having predetermined lattice constant on the substrate, hereby growing and forming an induction layer having optimal orientation (step 210), wherein the induction layer may be made by chemical vapor deposition, physical vapor deposition, or atomic layer deposition (ALD). And finally, the poly-silicon material is deposited on the induction layer by means of Plasma Enhanced Chemical Vapor Deposition (step 220). Herein, the material deposited to form the induction layer (for example: AIN etc.) is provided with the lattice constant close to that of silicon. As such, the induction layer can be used to reduce the disorder of stress and lattices due to the lattice mismatch, and induce the silicon atoms of the poly-silicon material to form regular arrangement, thus a poly-silicon thin film of superior quality may be formed with minimum thickness. In the above process, the deposition of poly-silicon material may be achieved through the ordinary Plasma Enhanced Chemical Vapor Deposition or Inductively-Coupled Plasma Chemical Vapor Deposition (ICP-CVD).

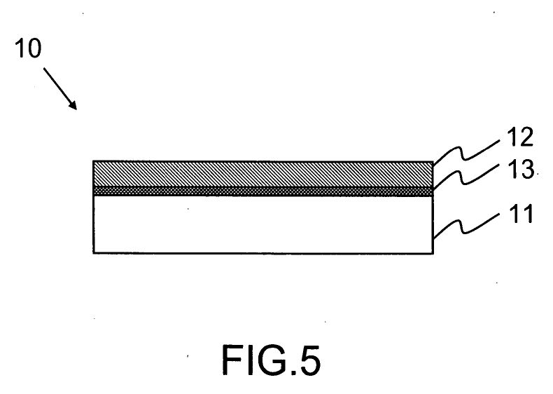

Moreover, referring to FIG. 5, a poly-silicon thin film element manufactured at low temperature according to the method mentioned above is shown. As shown in FIG. 5, a poly-silicon thin film element 10 is composed of a substrate 11, an induction layer 13, and a poly-silicon thin film 12, wherein the induction layer 13 is formed on the substrate 11, and the poly-silicon thin film 12 is formed on the induction layer 13. As such, the induction layer is in optimal orientation having its lattice constant close to that of the silicon and is made of aluminum nitride, etc.

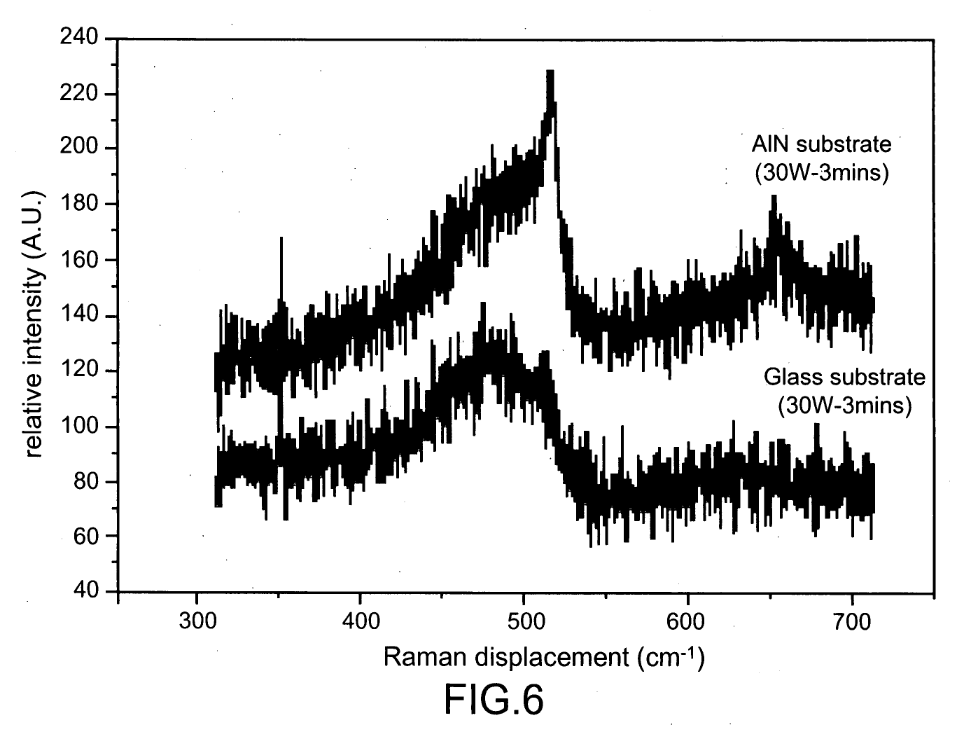

In addition, referring to FIG. 6, a graph of relative intensity vs. Raman displacement for the Raman spectrum obtained by an experiment on a poly-silicon thin film having an auxiliary induction layer made of aluminum nitride is shown. The two curves shown in FIG. 6 represent the Raman spectrum of a poly-silicon thin film formed on an AIN substrate and a glass substrate respectively. The spectrums having peak values of relative intensity clearly indicate the existence and characteristics of the poly-silicon thin films.

Summing up the above, the deposition of the poly-silicon material is achieved by making use of high density plasma in cooperation with the bias voltage applied on the substrate, thus enough energy is provided to the silicon atoms, so that the silicon atoms could be in better orientation, hereby producing a poly-silicon thin film of superior quality.

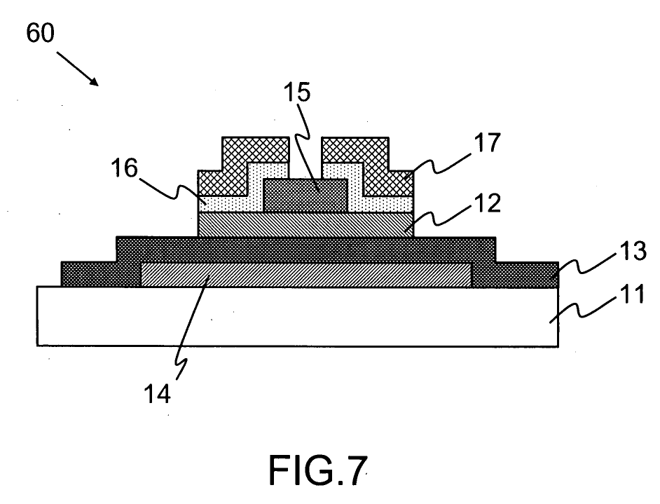

Furthermore, in addition to producing a poly-silicon thin film having a better structure arrangement, the material used to form the induction layer may be used in a display for heat dissipation of its substrate, or used in a gate insulation layer of a thin-film-transistor (TFT) element, due to its superior heat conduction and dielectric insulation capabilities, to reduce production cost and time. Referring to FIG. 7, a schematic diagram of a structure of a low temperature poly-silicon thin film transistor 60 is shown. As shown in FIG. 7, firstly, a gate electrode 14 is made on a substrate 11. Next, an induction layer 13 is formed on the substrate and overlaying the gate electrode 14. Then, a poly-silicon thin film 12 is formed on the induction layer 13. Subsequently, a barrier layer 15 is formed on the poly-silicon thin film 12. Then, doped layers 16 are formed on both sides of the barrier layer 15 to serve as channels, and the source electrode/ drain electrode 17 are formed on the doped layer 16, hereby realizing a low temperature poly-silicon thin film transistor 60.

The production of the above-mentioned structure is described as follows. Upon finishing the gate electrode metal pattern on a glass or silicon substrate, the glass or silicon substrate with the gate electrode on it are sent to the equipment of inductively-coupled plasma chemical vapor deposition (ICP) for conducting the deposition of an induction layer made of material such as aluminum nitride (AIN), for 10 minutes. During the deposition process, the operation temperature is about 150° C., the chamber pressure is about 30 mtorr, and the power utilized for the ICP is about 800 W, thus depositing to form an AIN gate electrode insulation layer having optimal orientation, that also serves as an ideal place for the subsequent deposition of poly-silicon material. Thus, in the same deposition chamber, the induced growth insulation layer, the poly-silicon active layer, and the poly-silicon doped layer can be formed sequentially to realize the structure of the element. In this manner of continuous growth, the quality of the thin film can be increased without being contaminated due to the vacuum breaking, thus realizing the poly-silicon thin film having high degree of crystallization and optimal orientation.

Knowing the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of directly depositing poly-silicon thin film at low temperature, comprising the following steps:
providing a substrate; and
applying a bias voltage on said substrate, and depositing a poly-silicon material on said substrate by means of the Plasma Chemical Vapor Deposition, thus said poly-silicon material is crystallized into a poly-silicon thin film through the induction of said bias voltage.

2. The method of directly depositing poly-silicon thin film at low temperature as claimed in claim 1, wherein said Plasma Chemical Vapor Deposition utilized is a Plasma-Enhanced Chemical Vapor Deposition.

3. The method of directly depositing poly-silicon thin film at low temperature as claimed in claim 1, wherein said Plasma Chemical Vapor Deposition utilized is an Inductively-Coupled Plasma Chemical Vapor Deposition (ICP-CVD).

4. The method of directly depositing poly-silicon thin film at low temperature as claimed in claim 3, wherein the proceeding of said Inductively-Coupled Plasma Chemical Vapor Deposition includes the following steps:
placing said substrate into a vacuum chamber;
injecting a gas having said poly-silicon material into said vacuum chamber;
generating an inductively-coupled electrical field in said vacuum chamber by making use of an induction coil, thus said gas is used to generate a high density plasma through the action of said inductively-coupled electrical field; and
diffusing said high density plasma to said substrate, so that said poly-silicon material is deposited on said substrate.

5. A method of directly depositing poly-silicon thin film at low temperature, comprising the following steps:
providing a substrate;
depositing a material having predetermined lattice constant on said substrate, thus forming an induction layer having optimal orientation; and
depositing a poly-silicon material on said induction layer by means of Plasma Chemical Vapor Deposition, thus said poly-silicon material is crystallized into said poly-silicon thin film through the induction of the said induction layer.

6. The method of directly depositing poly-silicon thin film at low temperature as claimed in claim 5, wherein the deposition method of said induction layer is selected from the group consisting of Chemical Vapor Deposition (CVD), Physical Vapor Deposition (PVD), and Atomic Layer Deposition (ALD).

7. The method of directly depositing poly-silicon thin film at low temperature as claimed in claim 5, wherein said material having said predetermined lattice constant close to the lattice constant of the silicon.

8. The method of directly depositing poly-silicon thin film at low temperature as claimed in claim 5, wherein in the step of depositing a material having predetermined lattice constant on said substrate, thus forming an induction layer having optimal orientation, aluminum nitride is deposited on said substrate.

9. The method of directly depositing poly-silicon thin film at low temperature as claimed in claim 5, wherein before the step of depositing a material having predetermined lattice constant on said substrate, thus forming an induction layer having optimal orientation, further comprising the step of: forming a gate electrode on said substrate.

10. The method of directly depositing poly-silicon thin film at low temperature as claimed in claim 5, wherein said Plasma Chemical Vapor Deposition utilized is a Plasma-Enhanced Chemical Vapor Deposition.

11. The method of directly depositing poly-silicon thin film at low temperature as claimed in claim 5, wherein said Plasma Chemical Vapor Deposition utilized is an Inductively-Coupled Plasma Chemical Vapor Deposition (ICP-CVD).

12. The method of directly depositing poly-silicon thin film at low temperature as claimed in claim 11, wherein said Inductively-Coupled Plasma Chemical Vapor Deposition includes the following steps:
placing said substrate into a vacuum chamber;
injecting a gas having said poly-silicon material into said vacuum chamber;
generating an inductively-coupled electrical field in said vacuum chamber by making use of an induction coil, thus said gas is used to generate a high density plasma through the action of said inductively-coupled electrical field; and
diffusing said high density plasma to said substrate, so that said poly-silicon material is deposited on said substrate.

13. The method of directly depositing poly-silicon thin film at low temperature as claimed in claim 5, wherein the step of depositing a poly-silicon material on said induction layer by means of Plasma Chemical Vapor Deposition, thus said poly-silicon material is crystallized into said poly-silicon thin film through the induction of the said induction layer is achieved through applying a bias voltage on said substrate, so that said poly-silicon material is crystallized into said poly-silicon thin film.

14. A low temperature poly-silicon thin film element, comprising:
a substrate;
an induction layer, disposed on said substrate and having a predetermined lattice constant and an optimal orientation; and
a poly-silicon thin film, disposed on said induction layer.

15. The low temperature poly-silicon thin film element as claimed in claim 14, wherein said predetermined lattice constant is close to the lattice constant of silicon.

16. The low temperature poly-silicon thin film element as claimed in claim 15, wherein the material having said predetermined lattice constant is aluminum nitride.

17. The low temperature poly-silicon thin film element as claimed in claim 14, wherein the method of forming said poly-silicon thin film is selected from a group consisting of: Plasma-Enhanced Chemical Vapor Deposition and Inductively-Coupled Plasma Chemical Vapor Deposition.

18. The low temperature poly-silicon thin film element as claimed in claim 14, further comprising:
a gate electrode, disposed between said substrate and said induction layer.

19. The low temperature poly-silicon thin film element as claimed in claim 14, further comprising;
a barrier layer, formed on said poly-silicon thin film;
at least a doped layer, formed on the edge of said barrier layer; and
at least a source electrode/drain electrode, formed on said doped layer.

20. An Inductively-Coupled Plasma Chemical Vapor Deposition equipment, used to deposit a low temperature poly-silicon thin film on a substrate, comprising:
a vacuum chamber, used to accommodate more than one kind of injected gases, and provided with a support stand used to place said substrate, said injected gas containing a poly-silicon material;
an induction coil, disposed outside said vacuum chamber, and is used to generate an inductively-coupled electrical field in said vacuum chamber, so that said gas in said vacuum chamber is reacted and transformed into a plasma, which is used to bombard said substrate with ions and is deposited on said substrate; and
a direct current bias voltage supply, electrically connected to said support stand, and is used to apply a bias voltage on said substrate disposed on said support stand, thus inducing said poly-silicon material deposited on said substrate to crystallize into said poly-silicon thin film.
